(19) United States
(12) Patent Application Publication
(10) Pub. No.: US 2008/0191188 A1
(43) Pub. Date: Aug. 14, 2008

(54) Multi bit phase-change random access memory devices and methods of forming the same

(75) Inventor: Chang-Wook Jeong, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/012,778

(22) Filed: Feb. 5, 2008

(30) Foreign Application Priority Data
Feb. 9, 2007 (KR) 10-2007-0013879

(51) Int. Cl. H01L 45/00

(52) U.S. Cl. 257/4; 438/102; 257/E45.002

(57) ABSTRACT

A phase-change random access memory (PRAM) device includes a first electrode and a second electrode on a substrate. A phase change pattern is interposed between the first and second electrodes. An interlayer insulating layer having a contact hole is provided on the substrate. The phase change pattern may be disposed in the contact hole. The phase change pattern includes a plurality of doping patterns having different doping concentrations. Methods of forming a multi-bit PRAM device are also disclosed.

### CROSS-REFERENCE TO RELATED APPLICATION

This application claims priority to Korean Patent Application No. 10-2007-0013879, filed Feb. 9, 2007, the disclosure of which is hereby incorporated herein by reference in its entirety.

### BACKGROUND

The present invention relates to semiconductor memory devices, and more particularly, to multi-bit phase-change random access memory (PRAM) devices and a methods of forming the same.

Semiconductor memory devices can be generally classified as volatile memory devices or non-volatile memory devices. A non-volatile memory device maintains data stored therein even when power is cut off. Accordingly, non-volatile memory devices are widely employed in mobile telecommunication systems, mobile memory devices, auxiliary memories of a digital devices, etc.

Extensive development work has been performed on new memory devices with structures that have non-volatile memory characteristics and that efficiently improve integration density. As a result, the phase-change random access memory (PRAM) device has been developed. A unit cell of a PRAM device includes an access device and a data storage element serially connected to the access device. The data storage element may include a lower electrode electrically connected to the access device, and a phase change material layer in contact with the lower electrode. The phase change material layer is a material layer that electrically switches between an amorphous state and a crystalline state, or between various resistivity states depending on the crystalline state of the material, in response to an applied current.

FIG. 1 is a cross-sectional view of a conventional PRAM device.

Referring to FIG. 1, a PRAM device includes a lower insulating layer 12 on a predetermined region of a semiconductor substrate 1, a lower electrode 14 in the lower insulating layer 12, an upper insulating layer 13 on the lower insulating layer 12, a bit line 18 on the upper insulating layer 13, a phase change pattern 16 in the upper insulating layer 13 and in contact with the lower electrode 14, and an upper electrode 17 electrically connected between the phase change pattern 16 and the bit line 18. The lower electrode 14 may be electrically connected to an access device, such as a diode or a transistor.

When a program current flows through the lower electrode 14, Joule heat is generated at an interface between the phase change pattern 16 and the lower electrode 14. The Joule heat converts a portion 20 (referred to as the “transition volume”) of the phase change pattern 16 into an amorphous or crystalline state. The resistivity of the transition volume 20 in the amorphous state is higher than the resistivity of the transition volume 20 in the crystalline state. Therefore, whether information stored in a unit cell of the PRAM device is a logic “1” or a logic “0” may be determined by sensing the current that flows through the transition volume 20 in a read mode.

As the transition volume 20 becomes larger, the program current may be proportionally increased. The access device should be designed to have a sufficient current driving capability to supply the program current. However, to improve the current driving capability, the area occupied by the access device may be increased. In general, the smaller the transition volume 20 is, the higher the integration density of the PRAM device becomes.

The integration density of a PRAM device may be significantly improved by storing two or more bits in a single cell. Accordingly, research into such devices is underway. Since the phase change material layer may have various resistance values depending on the ratio of crystalline to amorphous material, it is theoretically possible for multiple bits of information, such as two or more bits, to be stored in a cell.

Multi-bit PRAM devices are disclosed, for example, in U.S. Patent Publication No. 2004-0178404 entitled “Multiple Bit Chalcogenide Storage Device.”

According to Publication No. 2004-0178404, a phase change memory cell includes three electrodes that are respectively in contact with an upper surface, a lower surface, and a side of a phase change material layer. A crystal state of an upper region of the phase change material layer is converted using the electrodes in contact with the upper surface and the side of the phase change material layer, and a crystal state of a lower region of the phase change material layer may be converted using the electrodes in contact with the lower surface and the side of the phase change material layer, so that two bits of information may be stored in each cell. However, the structure and manufacturing process of the phase change memory cell may be complicated, and a peripheral circuit for supplying the program current may have a complicated structure.

### SUMMARY

A PRAM device includes a first electrode disposed on a substrate and a second electrode spaced from the first electrode. A phase change pattern is interposed between the first and second electrodes. The phase change pattern includes a plurality of doping patterns. The doping patterns have different doping concentrations from each other.

In some embodiments, an interlayer insulating layer may be provided on the substrate and having a contact hole passing therethrough. The phase change pattern may be formed in the contact hole. A contact spacer may be interposed between the phase change pattern and the interlayer insulating layer.

The width of the portion of the phase change pattern adjacent to the first electrode may be equal to or narrower than that of the first electrode. Also, the width of the portion of the phase change pattern adjacent to the second electrode may be equal to or narrower than that of the second electrode.

In some embodiments, the phase change pattern may include one or more of bulk patterns. The bulk pattern may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer. The doping patterns may be formed of a material in which N, O, Bi, Sn, B, In, Ti, C, and/or Si is added to the same material layer as the bulk patterns.

In some embodiments, the phase change pattern may include a first doping pattern, and a second doping pattern disposed on the first doping pattern. The second doping pattern may have a higher doping concentration than the first doping pattern.

In further embodiments, the phase change pattern may include a first bulk pattern interposed between the first electrode and the first doping pattern. A second bulk pattern may be interposed between the first doping pattern and the second doping pattern. A third bulk pattern may be interposed between the second doping pattern and the second electrode.

Methods of fabricating a multi-bit PRAM device include forming a first electrode on a substrate. A phase change pattern having a plurality of doping patterns is formed on the first electrode. The doping patterns have different doping concentrations from each other. A second electrode is formed on the phase change pattern.

In some embodiments, an interlayer insulating layer may be formed on a substrate. A contact hole may be formed to pass through the interlayer insulating layer. The phase change pattern may be formed in the contact hole. A contact spacer may be formed between the interlayer insulating layer and the phase change pattern.

In some embodiments, the first electrode may be formed in the contact hole.

Forming the phase change pattern may include forming a bulk pattern in the contact hole and in contact with the first electrode, forming a first doping pattern by performing a first ion implantation process into the bulk pattern, and forming a second doping pattern by performing a second ion implantation process into the bulk pattern having the first doping pattern. The first doping pattern and the first electrode may be spaced apart from each other, and the first and second doping patterns may be spaced apart from each other.

The bulk pattern may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer. The doping patterns may be formed by doping N, O, Bi, Sn, B, In, Ti, C and/or Si into the same material layer as the bulk pattern.

The phase change pattern may be formed by depositing a first bulk pattern in contact with the first electrode in the contact hole, depositing a first doping pattern on the first bulk pattern, and depositing a second doping pattern on the first doping pattern. A second bulk pattern may be deposited between the first doping pattern and the second doping pattern. A third bulk pattern may be deposited on the second bulk pattern.

The portion of the phase change pattern adjacent to the first electrode may have a width equal to or narrower than the first electrode. Also, the portion of the phase change pattern adjacent to the second electrode may have a width equal to or narrower than the second electrode.

### BRIEF DESCRIPTION OF THE DRAWINGS

The accompanying drawings, which are included to provide a further understanding of the invention and are incorporated in and constitute a part of this application, illustrate certain embodiment(s) of the invention. In the drawings:

FIG. 1 is a partial cross-sectional view of a conventional phase-change random access memory (PRAM) device.

FIG. 2 is an equivalent circuit diagram of a part of a cell array region of a PRAM device according to some embodiments of the present invention.

FIG. 3 is a top view of a part of a cell array region of a PRAM device according to some embodiments of the present invention.

FIG. 4 is a cross-sectional view taken along line I-I′ of FIG. 3, illustrating a PRAM device according to a some embodiments of the present invention.

FIG. 5 is a graph illustrating a phase change pattern of a PRAM device according to some embodiments of the present invention.

FIGS. 6 and 7 are graphs illustrating current and resistance characteristics of a phase change pattern according to some embodiments of the present invention.

FIG. 8 is a cross-sectional view taken along line I-I′ of FIG. 3, illustrating a PRAM device according to further embodiments of the present invention.

FIG. 9 is an equivalent circuit diagram of a part of a cell array region of a PRAM device according to further embodiments of the present invention.

FIG. 10 is a cross-sectional view of a PRAM device according to further embodiments of the present invention.

FIGS. 11 to 20 are cross-sectional views taken along line I-I′ of FIG. 3, illustrating methods of forming a PRAM device according to some embodiments of the present invention.

### DETAILED DESCRIPTION OF EMBODIMENTS OF THE INVENTION

Embodiments of the present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

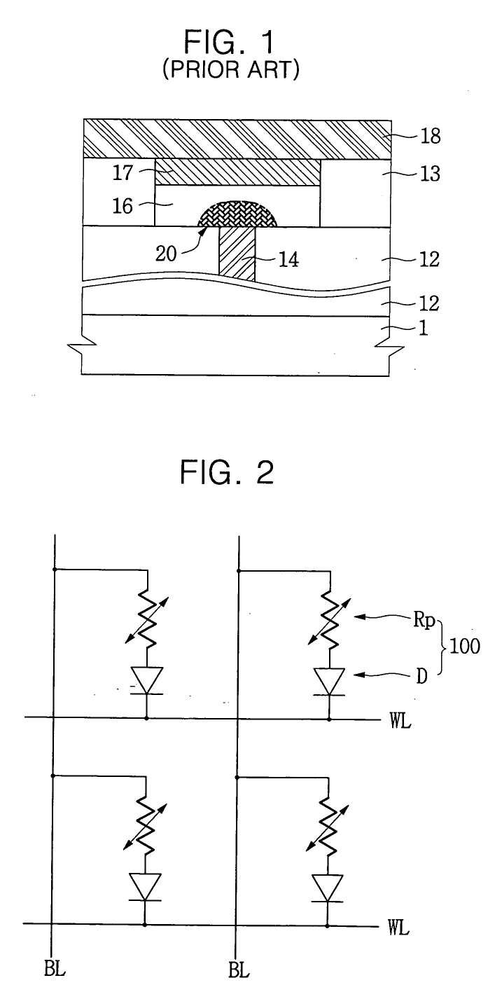

FIG. 2 is an equivalent circuit diagram of a portion of a cell array region of a phase-change random access memory (PRAM) device according to some embodiments of the present invention.

Referring to FIG. 2, a plurality of word lines (WL), a plurality of bit lines (BL) and a plurality of phase change memory cells 100 may be provided in the cell array region. The bit lines BL may cross the word lines WL. The phase change memory cells 100 may be disposed at intersections of the word lines WL and the bit lines BL.

Each of the phase change memory cells 100 may include a phase change pattern (Rp) electrically connected to one of the bit lines BL, and a switching device D electrically connected to the phase change pattern Rp. The switching device may include a diode, for example. One end of the diode D may be electrically connected to one of the word lines WL. Alternatively, the switching device may be a metal-oxide semiconductor (MOS) transistor.

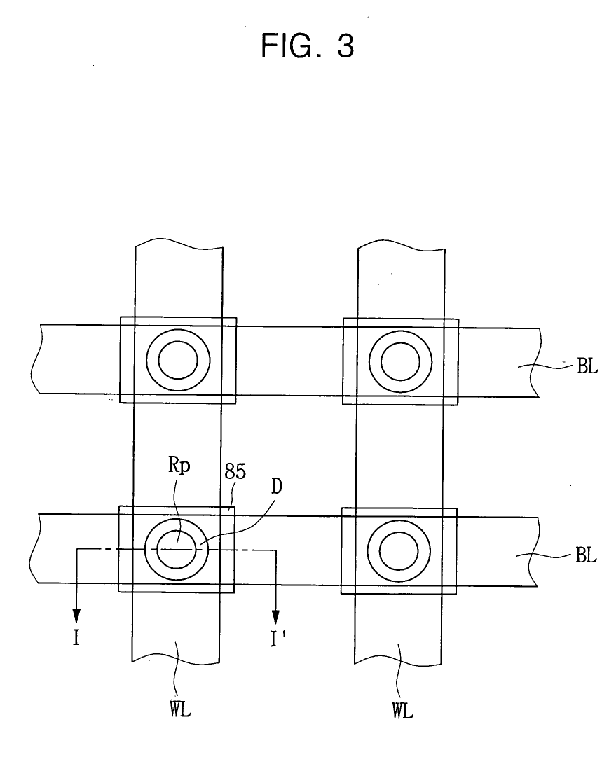

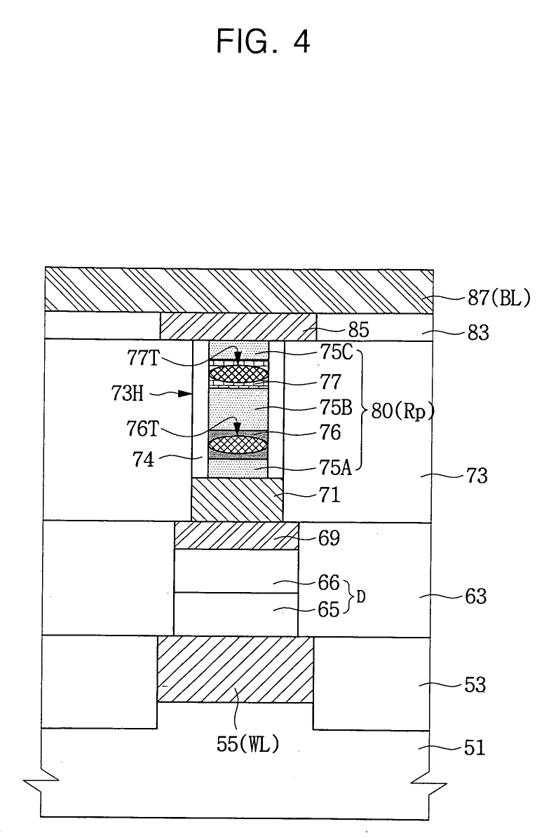

FIG. 3 is a top view of a portion of a cell array region of a PRAM device according to some embodiments of the present invention. In other words, FIG. 3 is a top view of a portion of the cell array region of FIG. 2, and FIG. 4 is a cross-sectional view taken along line I-I′ of FIG. 3, illustrating a PRAM device according to some embodiments of the present invention.

Referring to FIGS. 3 and 4, a PRAM device according to some embodiments of the present invention may include a word line (WL) 55 and a bit line (BL) 87, both of which are provided on a substrate 51. The substrate 51 may be a semiconductor substrate, such as a silicon substrate. The word line WL 55 may be defined by an isolation layer 53 on the substrate 51. The isolation layer 53 may be an insulating layer, such as a silicon oxide layer, a silicon nitride layer, a silicon oxynitride layer, and/or a combination thereof.

The word line 55 may include impurity ion implantation regions. Alternatively, the word line 55 may include a conductive line stacked on the substrate 51. The conductive line may include a metal line and/or an epitaxial semiconductor pattern.

A lower insulating layer 63 may be provided on the word line 55 and the isolation layer 53. The lower insulating layer 63 may be an insulating layer, such as a silicon oxide layer, a silicon nitride layer, a silicon oxynitride layer, and/or a combination thereof. A diode D may be disposed within the lower insulating layer 63. The diode D may include a first semiconductor pattern 65 and a second semiconductor pattern 66.

The first semiconductor pattern 65 may be an n-type or p-type semiconductor layer. The second semiconductor pattern 66 may be a semiconductor layer having a different conductivity type from the first semiconductor pattern 65. For example, when the first semiconductor pattern 65 includes an n-type semiconductor layer, the second semiconductor pattern 66 may include a p-type semiconductor layer.

The first semiconductor pattern 65 and the second semiconductor pattern 66 may be sequentially stacked on the word line 55. In this case, the first semiconductor pattern 65 may be in contact with the word line 55. A diode electrode 69 may be disposed on the second semiconductor pattern 66. The diode electrode 69 may include a conductive layer, such as a metal layer and/or a metal silicide layer. However, the diode electrode 69 may be omitted from the structure.

An interlayer insulating layer 73 may be provided on the diode D and the lower insulating layer 63. The interlayer insulating layer 73 may include an insulating layer, such as a silicon oxide layer, a silicon nitride layer, a silicon oxynitride layer, and/or a combination thereof. A contact hole 73H may be formed passing through the interlayer insulating layer 73.

A first electrode 71 may be formed to at least partially fill a lower end of the contact hole 73H. In this case, the diameter of the first electrode 71 may be the same as that of the contact hole 73H. The first electrode 71 may be in contact with the diode electrode 69, if present. In some embodiments, the first electrode 71 may be in contact with the second semiconductor pattern 66. The first electrode 71 may include a Ti layer, a TiN layer, a TiAlN layer, a W layer, a WN layer, a Si layer, a Ta layer, a TaN layer, a TaCN layer, and/or a WCN layer.

A phase change pattern (Rp) 80 is formed in the contact hole 73H on the first electrode 71. In some embodiments (not shown), the width of the portion of the phase change pattern 80 adjacent to the first electrode 71 may be the same as that of the first electrode 71.

As shown in FIG. 4, a contact spacer 74 may be provided on sidewalls of the contact hole 73H between the phase change pattern 80 and the interlayer insulating layer 73. That is, the contact spacer 74 may be formed on sidewalls of the contact hole 73H on the first electrode 71. Accordingly, in some embodiments, the width of the portion of the phase change pattern 80 adjacent to the first electrode 71 may be narrower than the width of the first electrode 71. The contact spacer 74 may include an insulating layer, such as a silicon oxide layer, a silicon nitride layer, a silicon oxynitride layer, and/or a combination thereof.

The phase change pattern 80 may include a first bulk pattern 75A, a first doping pattern 76, a second bulk pattern 75B, a second doping pattern 77, and a third bulk pattern 75C, which are sequentially stacked on the first electrode 71.

Each of the first, second and third bulk patterns 75A, 75B and 75C may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer. The first bulk pattern 75A, the second bulk pattern 75B, and/or the third bulk pattern 75C may be formed of the same material.

Each of the first and second doping patterns 76 and 77 may be formed by doping N, O, Bi, Sn, B, In, Ti, C and/or Si into a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer. Also, the doping patterns 76 and 77 may be formed by doping N, O, Bi, Sn, B, In, Ti, C and/or Si into a layer that is the same material as the bulk patterns 75A, 75B, and 75C.

The first doping pattern 76 may have a higher electrical resistance than the first and second bulk patterns 75A and 75B. Similarly, the second doping pattern 77 may have a higher electrical resistance than the second and third bulk patterns 75B and 75C. The first doping pattern 76 may have a different doping concentration from the second doping pattern 77. That is, the first doping pattern 76 may have a different electrical resistance from the second doping pattern 77. For example, the second doping pattern 77 may have a higher doping concentration than the first doping pattern 76. In this case, the second doping pattern 77 may have a higher electrical resistance than the first doping pattern 76. For example, if N and/or C is doped into the first doping pattern 76 and the second doping pattern 77, a higher doping concentration would result in higher electrical resistance. However, if Ti is doped into the first doping pattern 76 and the second doping pattern 77, a higher doping concentration would result in lower electrical resistance.

An upper insulating layer 83 is formed on the interlayer insulating layer 73. The upper insulating layer 83 may include an insulating layer, such as a silicon oxide layer, a silicon nitride layer, a silicon oxynitride layer, and/or a combination thereof.

A second electrode 85 is formed in the upper insulating layer 83 and is in contact with the phase change pattern 80. In particular, the second electrode 85 may be on the contact hole 73H and may be in contact with the third bulk pattern 75C. The width of the portion of the phase change pattern 80 adjacent to the second electrode 85 may be equal to or narrower than the width of the second electrode 85.

The bit line 87 may be on the upper insulating layer 83 and may contact the second electrode 85. The bit line 87 may be electrically connected to the word line 55 through the second electrode 85, the phase change pattern 80, the first electrode 71, the diode electrode 69, and the diode D.

The second electrode 85 may include a Ti layer, a TiN layer, a TiAlN layer, a W layer, a WN layer, a Si layer, a Ta layer, a TaN layer, a TaCN layer, and/or a WCN layer. The bit line 87 may include a conductive layer, such as a metal layer, a polysilicon layer, a metal silicide layer, and/or a combination thereof.

When an operating current is supplied to the phase change pattern 80 through the bit line 87 and the word line 55, a first transition volume 77T may be generated in the second doping pattern 77, and a second transition volume 76T may be generated in the first doping pattern 76. The size of the first and second transition volumes 77T and 76T may be determined by the size and doping concentration of the doping patterns 76 and 77. Thus, the size of the first and second transition volumes 77T and 76T may be considerably reduced. Accordingly, the operating current supplied to the phase change pattern 80 may be reduced.

In some embodiments (not shown), the first doping pattern 76 and the second doping pattern 77 may be in contact with each other. In that case, the phase change pattern 80 may include the first bulk pattern 75A, the first doping pattern 76, the second doping pattern 77, and the third bulk pattern 75C, which are sequentially stacked.

In still further embodiments, the first bulk pattern 75A may be omitted. In that case, the first doping pattern 76 may be in direct contact with the first electrode 71.

In further embodiments, the third bulk pattern 75C may be omitted, in which case, the second doping pattern 77 may be in direct contact with the second electrode 85.

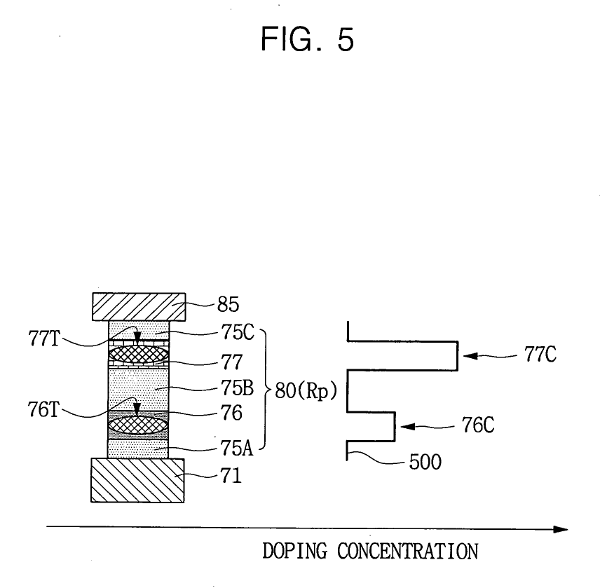

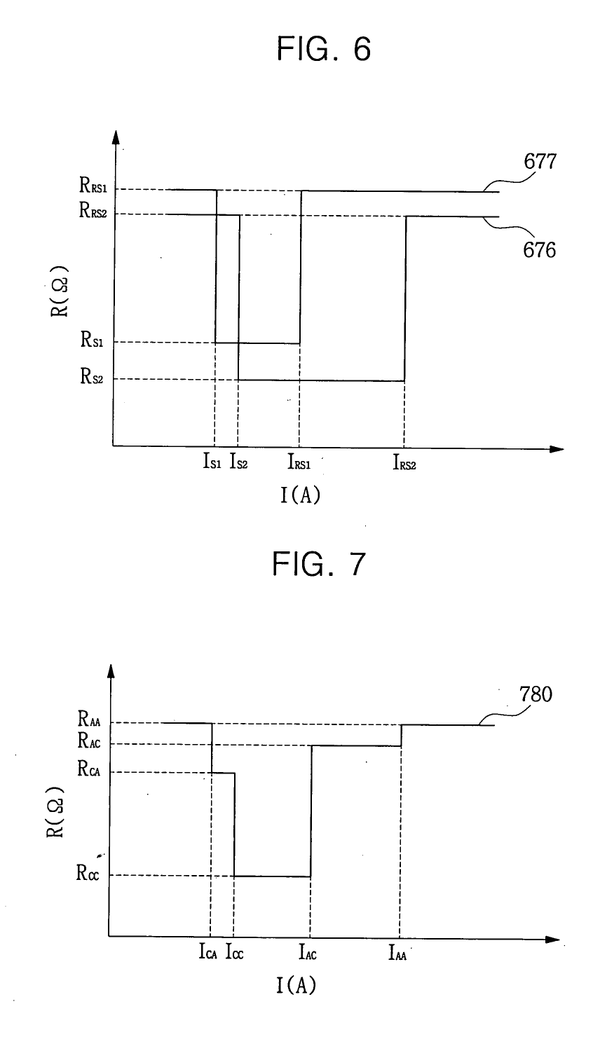

FIG. 5 is a graph illustrating a phase change pattern according to some embodiments of the present invention, and FIGS. 6 and 7 are graphs illustrating current and resistance characteristics of a phase change pattern according to some embodiments of the present invention. Some operations of a PRAM device according to embodiments of the present invention will be described below with reference to FIGS. 5 to 7.

Referring to FIG. 5, a PRAM device according to some embodiments of the present invention may include a first electrode 71, a phase change pattern (Rp) 80, and a second electrode 85, as described above with reference to FIG. 4. The phase change pattern 80 may include a first bulk pattern 75A, a first doping pattern 76, a second bulk pattern 75B, a second doping pattern 77, and a third bulk pattern 75C, which are sequentially stacked on the first electrode 71. Accordingly, the first electrode 71, the first bulk pattern 75A, the first doping pattern 76, the second bulk pattern 75B, the second doping pattern 77, the third bulk pattern 75C, and the second electrode 85 may be electrically connected in series.

A horizontal axis of FIG. 5 represents doping concentration, and a graph 500 represents a doping concentration at each layer of the phase change pattern 80. As plotted in graph 500, the first doping pattern 76 may have a first doping concentration 76C, and the second doping pattern 77 may have a second doping concentration 77C. The second doping concentration 77C may be higher than the first doping concentration 76C. In this case, the second doping pattern 77 may have a higher electrical resistance than the first doping pattern 76. Also, the first doping pattern 76 may have a higher doping concentration than the first bulk pattern 75A, the second bulk pattern 75B, and/or the third bulk pattern 75C. That is, the first doping pattern 76 may have a higher electrical resistance than the first bulk pattern 75A, the second bulk pattern 75B, and/or the third bulk pattern 75C.

Referring to FIGS. 5 and 6, graph 677 in FIG. 6 represents current and resistance characteristics of the second (higher doped) doping pattern 77, and graph 676 in FIG. 6 represents current and resistance characteristics of the first doping pattern 76. Current is plotted on the horizontal axis I of FIG. 6, and the unit of the horizontal axis is ampere (A). Also, electrical resistance is plotted on the vertical axis R of FIG. 6, and the unit of the vertical axis is ohm (Q).

When a current flows through the second doping pattern 77, the current and resistance characteristics as shown in graph 677 may be exhibited. More specifically, when the second doping pattern 77 is in an amorphous state, the pattern has a first resistance RRS1. When a first current IS1 is supplied to the second doping pattern 77, a first transition volume 77T may be formed in the second doping pattern 77. The first transition volume 77T may be in a crystalline state. In this case, the resistance of the second doping pattern 77 becomes RS1, which is lower than the first resistance RRS1. Subsequently, when a second current IRS1, which is higher than the first current IS1, is supplied to the second doping pattern 77, the second doping pattern 77 may be converted into the amorphous state. In this case, the second doping pattern 77 has the first resistance RRS1.

When a current flows through the first doping pattern 76, the current and resistance characteristics shown in graph 676 may be obtained. More specifically, when the first doping pattern 76 is in an amorphous state, a third resistance RRS2 lower than the first resistance RRS1 may be exhibited. When a third current IS2, which is higher than the first current IS1, is supplied to the first doping pattern 76, a second transition volume 76T may be formed in the first doping pattern 76. The second transition volume 76T may be in a crystalline state. In this case, the resistance of the first doping pattern 76 changes to RS2, which is lower than the second resistance RS1 and the third resistance RRS2. Subsequently, when a fourth current IRS2, which is higher than the third current IS2 and the second current IRS1, is supplied to the first doping pattern 76, the first doping pattern 76 may be converted into the amorphous state. In this case, the first doping pattern 76 has the third resistance RRS2.

Referring to FIGS. 5 to 7, graph 780 represents current and resistance characteristics of the phase change pattern 80. Current is plotted in the horizontal axis I of FIG. 7, and the unit of the horizontal axis is ampere (A). A vertical axis R of FIG. 7 represents electrical resistance, and the unit of the vertical axis is ohm (Ω).

When a current flows through the phase change pattern 80, the current and resistance characteristics of graph 780 may be obtained. In this case, graph 780 may show substantially the same trace as a combination of graphs 677 and 676 of FIG. 6.

More specifically, when the first and second doping patterns 76 and 77 are in an amorphous state, the phase change pattern 80 may have a first composite resistance RAA. The first composite resistance RAA may be construed as a value corresponding to a series connection of the first resistance RRS1 and the third resistance RRS2. When a first program current ICA is applied to the phase change pattern 80, the first transition volume 77T may be generated in the second doping pattern 77. The first transition volume 77T may be in a crystalline state. In this case, the phase change pattern 80 may have a second composite resistance RCA that is lower than the first composite resistance RAA. The second composite resistance RCA may be construed as a value corresponding to a series connection of the second resistance RS1 and the third resistance RRS2.

When a second program current ICC higher than the first program current ICA is applied to the phase change pattern 80, the second transition volume 76T may be generated in the first doping pattern 76. The second transition volume 76T may be in a crystalline state. In this case, the phase change pattern 80 may have a third composite resistance RCC that is lower than the second composite resistance RCA. The third composite resistance RCC may be construed as a value corresponding to a series connection of the second resistance RS1 and the fourth resistance RS2.

When a third program current IAC that is higher than the second program current ICC is applied to the phase change pattern 80, the second doping pattern 77 may converted into the amorphous state. In this case, the phase change pattern 80 has a fourth composite resistance RAC. The fourth composite resistance RAC may be lower than the first composite resistance RAA and higher than the second composite resistance RCA. The fourth composite resistance RAC may be construed as a value corresponding to a series connection of the first resistance RRS1 and the fourth resistance RS2.

Further, when a fourth program current IAA that is higher than the third program current IAC is applied to the phase change pattern 80, the first doping pattern 76 may be converted into the amorphous state. In this case, the phase change pattern 80 has the first composite resistance RAA.

As described above, the phase change pattern 80 may have the first to fourth composite resistances RAA, RCA, RCC and RAC in response to application of the first to fourth program currents ICA, ICC, IAC, and IAA. As a result, the phase change pattern 80 may be programmed into four states, in which case, the phase change pattern 80 may store two bits of data.

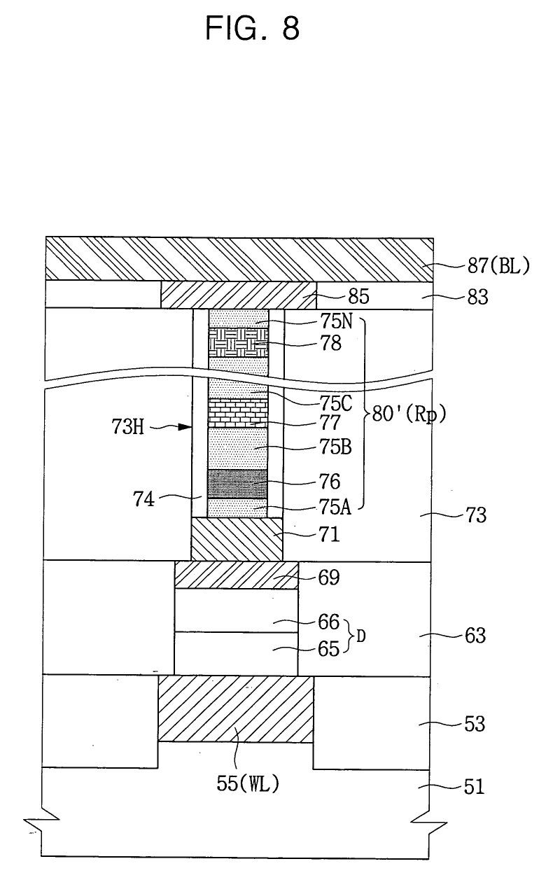

FIG. 8 is a cross-sectional view taken along line I-I′ of FIG. 3, illustrating PRAM devices according to further embodiments of the present invention.

Referring to FIGS. 3 and 8, a PRAM device according to further embodiments of the present invention may include a word line (WL) 55, and a bit line (BL) 87 on a substrate 51. An isolation layer 53, a lower insulating layer 63, a diode D, a diode electrode 69, an interlayer insulating layer 73, a contact hole 73H, a first electrode 75, an upper insulating layer 83, and a second electrode 85 may be provided on the substrate 51. The diode D may include a first semiconductor pattern 65 and a second semiconductor pattern 66. Only differences from the previous embodiments will be described below with reference to FIG. 4.

A phase change pattern (Rp) 80′ may be disposed on the first electrode 71 in the contact hole 73H. A contact spacer 74 may be provided between the phase change pattern 80′ and the interlayer insulating layer 73. That is, the contact spacer 74 may be disposed on sidewalls of the contact hole 73H on the first electrode 71, in which case, the width of the portion of the phase change pattern 80′ adjacent to the first electrode 71 may be narrower than the width of the first electrode 71.

However, the contact spacer 74 may be omitted, in which case the width of the portion of the phase change pattern 80′ adjacent to the first electrode 71 may be equal to that of the first electrode 71.

The phase change pattern 80′ may include a first bulk pattern 75A, a first doping pattern 76, a second bulk pattern 75B, a second doping pattern 77, a third bulk pattern 75C, and so on, up to an nth doping pattern 78, and an nth bulk pattern 75N, which are sequentially stacked. A plurality of doping patterns and a plurality of bulk patterns may be interposed between the third bulk pattern 75C and the nth doping pattern 78.

Each of the first bulk pattern 75A, the second bulk pattern 75B, the third bulk pattern 75C, and the nth bulk pattern 75N may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer. The first bulk pattern 75A, the second bulk pattern 75B, the third bulk pattern 75C, and the nth bulk pattern 75N may be formed of the same material layer.

Each of the first doping pattern 76, the second doping pattern 77, and the nth doping pattern 78 may be formed of a material layer including a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer that is doped with N, O, Bi, Sn, B, In, Ti, C and/or Si.

The first doping pattern 76 may have a higher electrical resistance than the first bulk pattern 75A, the second bulk pattern 75B, the third bulk pattern 75C, and the nth bulk pattern 75N. Similarly, the second and nth doping patterns 77 and 78 may have a higher electrical resistance than the first bulk pattern 75A, the second bulk pattern 75B, the third bulk pattern 75C, and the nth bulk pattern 75N. The first, second and nth doping patterns 76 to 78 may have different doping concentrations from each other. That is, the first, second and nth doping patterns 76 to 78 may have different electrical resistances from each other. For example, the second doping pattern 77 may have a higher doping concentration than the first doping pattern 76. In this case, the second doping pattern 77 may have a higher electrical resistance than the first doping pattern 76.

In some embodiments, the second bulk pattern 75B, and the third bulk pattern 75C may be omitted, in which case, the second doping pattern 77 may be in contact with the first and nth doping patterns 76 and 78.

In still further embodiments, the first bulk pattern 75A may be omitted, in which case, the first doping pattern 76 may be in direct contact with the first electrode 71.

In yet further embodiments, the nth bulk pattern 75N may be omitted, in which case, the nth doping pattern 78 may be in direct contact with the second electrode 85.

As a result, the phase change pattern 80′ may store multiple bits of data.

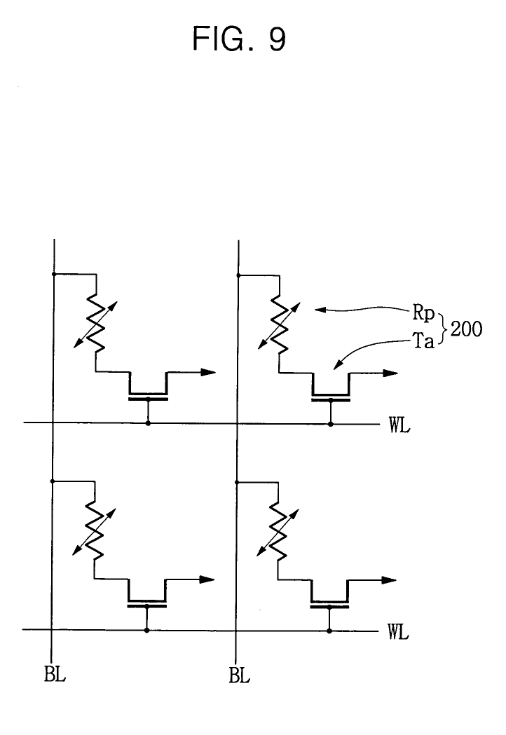

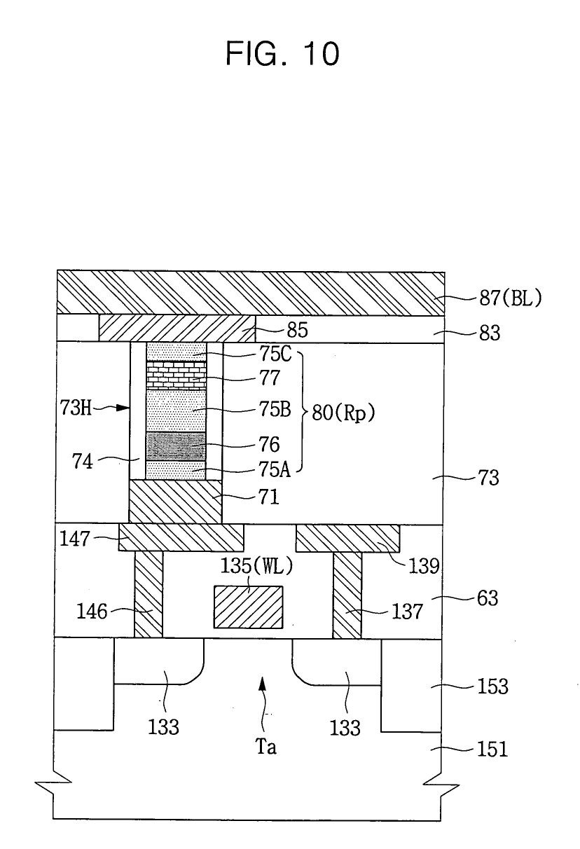

FIG. 9 is an equivalent circuit diagram of a portion of a cell array region of a PRAM device according to a still further embodiments of the present invention, and FIG. 10 is a cross-sectional view of a PRAM device according to further embodiments of the present invention.

Referring to FIG. 9, a plurality of word lines WL, a plurality of bit lines BL and a plurality of phase change memory cells 200 may be provided in a cell array region of the PRAM device according to embodiments of the present invention. The bit lines BL may cross the word lines WL. The phase change memory cells 200 may be disposed at intersections of the word lines WL and the bit lines BL.

Each of the phase change memory cells 200 may include a phase change pattern Rp electrically connected to one of the bit lines BL, and a switching device electrically connected to the phase change pattern Rp. The switching device may include a MOS transistor Ta. A gate of the MOS transistor Ta may be electrically connected to one of the word lines WL.

Referring to FIG. 10, a PRAM device according to embodiments of the present invention may include a word line (WL) 135 and a bit line (BL) 87, both of which are provided on a substrate 151. The substrate 151 may be a semiconductor substrate, such as a silicon substrate.

An isolation layer 153 defining an active region may be disposed in the substrate 151. The isolation layer 153 may include an insulating layer, such as a silicon oxide layer, a silicon nitride layer, a silicon oxynitride layer, and/or a combination thereof. The word line WL may serve as the gate electrode 135 for the transistor Ta. The gate electrode 135 may be formed of a conductive layer, such as a polysilicon layer, a metal layer, a metal silicide layer, and/or a combination thereof. Source and drain regions 133 may be disposed in the active region on both sides of the gate electrode 135.

The gate electrode 135, the substrate 151, and the source and drain regions 133 may form a MOS transistor Ta.

The MOS transistor Ta and the isolation layer 153 may be covered with a lower insulating layer 63. The lower insulating layer 63 may be an insulating layer such as a silicon oxide layer, a silicon nitride layer, a silicon oxynitride layer, and/or a combination thereof.

A source line 139 and a drain pad 147 may be disposed in the lower insulating layer 63. The source line 139 may be electrically connected to one of the source and/or drain regions 133 through a source plug 137 passing through the lower insulating layer 63. The drain pad 147 may be electrically connected to the other of the source and/or drain regions 133 through a drain plug 146 passing through the lower insulating layer 63. The source line 139, the drain pad 147, the source plug 137, and the drain plug 146 may be formed of a conductive layer.

An interlayer insulating layer 73 may be provided on the lower insulating layer 63. The interlayer insulating layer 73 may include an insulating layer, such as a silicon oxide layer, a silicon nitride layer, a silicon oxynitride layer, and/or a combination thereof. A contact hole 73H may be formed to pass through the interlayer insulating layer 73.

A first electrode 71 may be formed at a lower end of the contact hole 73H. In this case, the first electrode 71 and the contact hole 73H may have the same diameter. The first electrode 71 may be in contact with the drain pad 147. The first electrode 71 may include a Ti layer, a TiN layer, a TiAlN layer, a W layer, a WN layer, a Si layer, a Ta layer, a TaN layer, a TaCN layer, and/or a WCN layer.

As illustrated in FIG. 10, a phase change pattern 80, a contact spacer 74, an upper insulating layer 83, a second electrode 85, and the bit line 87 may be included as described above with reference to FIG. 4.

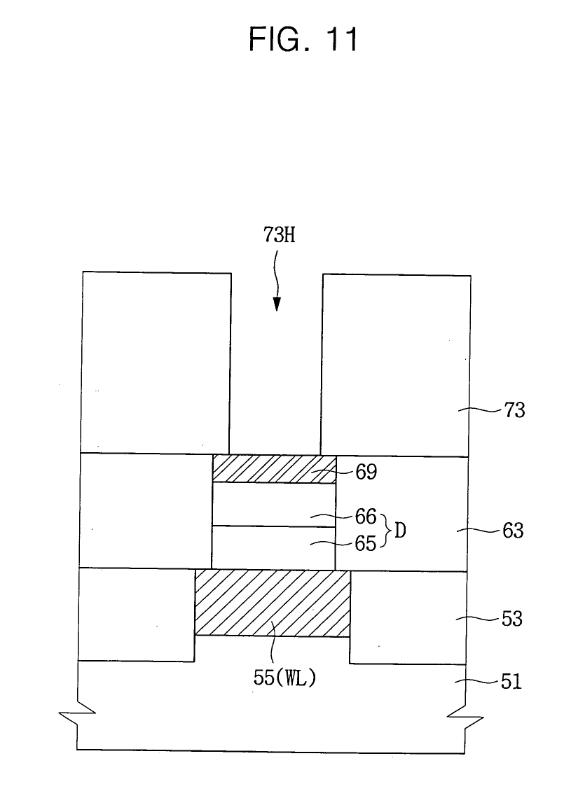

FIGS. 11 to 16 are cross-sectional views taken along line I-I′ of FIG. 3, illustrating methods of forming a PRAM device according to a first exemplary embodiment of the present invention.

Referring to FIGS. 3 and 11, an isolation layer 53 defining a word line (WL) 55 may be formed in a substrate 51. The substrate 51 may be a semiconductor substrate, such as a silicon substrate. The isolation layer 53 may be formed, for example, by a trench isolation technique. The isolation layer 53 may include an insulating layer, such as a silicon oxide layer, a silicon nitride layer, a silicon oxynitride layer, and/or a combination thereof. The word line 55 may be formed of an impurity ion implantation region. Alternatively, the word line 55 may be formed of a conductive line stacked on the substrate 51. The conductive line may include a metal line and/or an epitaxial semiconductor pattern.

A lower insulating layer 63 may be formed on the word line 55 and the isolation layer 53. The lower insulating layer 63 may include an insulating layer, such as a silicon oxide layer, a silicon nitride layer, a silicon oxynitride layer, and/or a combination thereof. Diodes D may be formed in the lower insulating layer 63. The diodes D may be formed, for example, by sequentially stacking a first semiconductor pattern 65 and a second semiconductor pattern 66 on a predetermined region of the word line 55.

The first semiconductor pattern 65 may be formed of an n-type or p-type semiconductor layer. The second semiconductor pattern 66 may be formed of a semiconductor layer having a different conductivity type from the first semiconductor pattern 65. For example, the first semiconductor pattern 65 may be formed of an n-type semiconductor layer, and the second semiconductor pattern 66 may be formed of a p-type semiconductor layer.

A diode electrode 69 may be formed on the second semiconductor pattern 66. The diode electrode 69 may include a conductive layer, such as a metal layer and/or a metal silicide layer. Top surfaces of the lower insulating layer 63 and the diode electrode 69 may be planarized. In this case, the top surface of the diode electrode 69 may be exposed.

An interlayer insulating layer 73 may be formed on the lower insulating layer 63. The interlayer insulating layer 73 may include an insulating layer, such as a silicon oxide layer, a silicon nitride layer, a silicon oxynitride layer, and/or a combination thereof. A contact hole 73H may be formed through the interlayer insulating layer 73 and exposing the diode electrode 69.

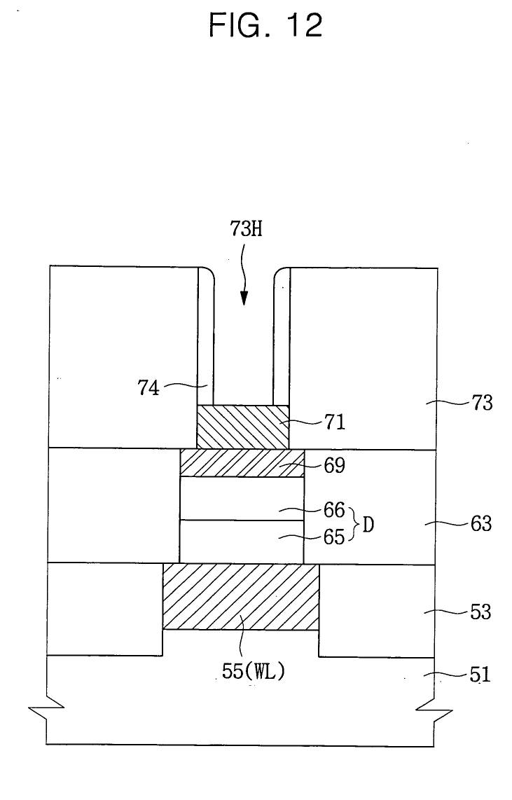

Referring to FIGS. 3 and 12, a first electrode 71 may be formed in a lower end of the contact hole 73H. The first electrode 71 may include a Ti layer, a TiN layer, a TiAlN layer, a W layer, a WN layer, a Si layer, a Ta layer, a TaN layer, a TaCN layer, and/or a WCN layer.

The first electrode 71 may be formed by forming a conductive layer in the contact hole 73H, and then etching-back the conductive layer. In this case, the first electrode 71 may have the same diameter as the contact hole 73H. Moreover, the first electrode 71 may be in contact with the diode electrode 69.

A contact spacer 74 may be formed on sidewalls of the contact hole 73H. The contact spacer 74 may include an insulating layer, such as a silicon oxide layer, a silicon nitride layer, a silicon oxynitride layer, and/or a combination thereof. The contact spacer 74 may be formed by forming the insulating layer on the substrate 51 having the first electrode 71 and then anisotropically etching the insulating layer until the first electrode 71 is exposed.

The contact spacer 74 may be disposed above the first electrode 71, and may cover the sidewalls of the contact hole 73H. However, in some embodiments, the contact spacer 74 may be omitted.

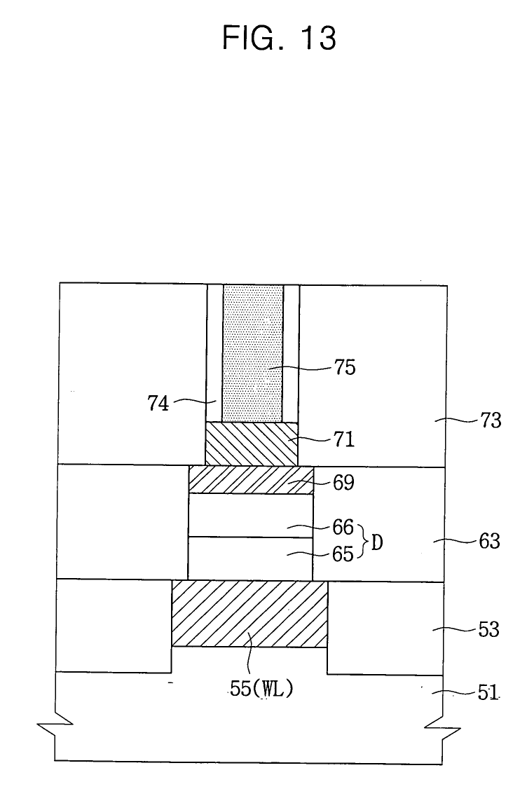

Referring to FIGS. 3 and 13, a bulk pattern 75 may be formed in the contact hole 73H on the first electrode 71. The bulk pattern 75 may include a chalcogenide alloy. In particular, the bulk pattern 75 may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

The bulk pattern 75 may be formed by forming a phase change material layer filling the contact hole 73H and on the interlayer insulating layer 73, and then planarizing the phase change material layer. The phase change material layer may be planarized by a chemical mechanical polishing (CMP) process and/or an etch-back process.

The bulk pattern 75 may be in contact with the first electrode 71. The bulk pattern 75 may be formed to have a narrower width than the first electrode 71. If the contact spacer 74 is omitted, the bulk pattern 75 may be formed to have the same width as the first electrode 71.

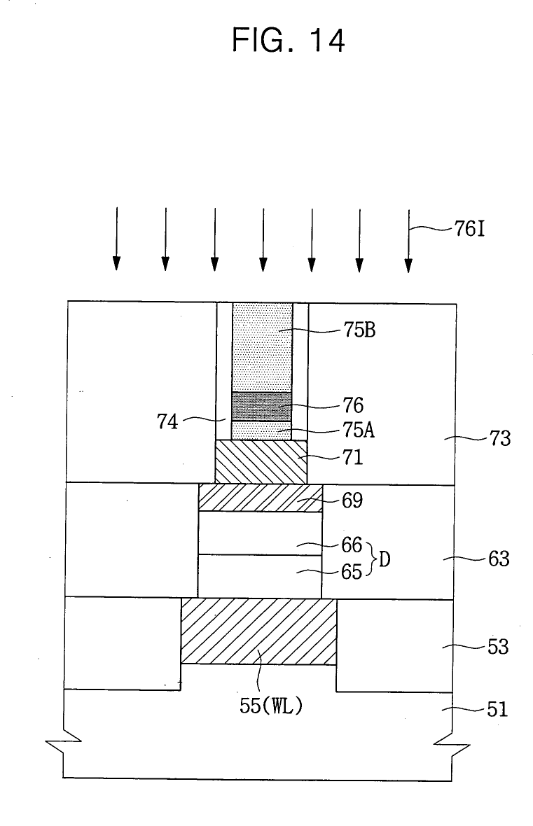

Referring to FIGS. 3 and 14, a first doping pattern 76 may be formed by performing a first ion implantation process 761 into the bulk pattern 75. The first doping pattern 76 may be formed by doping N, O, Bi, Sn, B, In, Ti, C and Si into the bulk pattern 75.

That is, the first doping pattern 76 may be formed by doping N, O, Bi, Sn, B, In, Ti, C and Si into a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

The first doping pattern 76 may be formed in a predetermined region of the bulk pattern 75 adjacent to the first electrode 71. In this case, the bulk pattern 75 may be divided into a first bulk pattern 75A, and a second bulk pattern 75B by the first doping pattern 76. The first bulk pattern 75A may remain between the first electrode 71 and the first doping pattern 76. The second bulk pattern 75B may remain on the first doping pattern 76. The first doping pattern 76 may have a different electrical resistance from the bulk patterns 75A and 75B. For example, the first doping pattern 76 may have a higher electrical resistance than the bulk patterns 75A and 75B.

Alternatively, the first doping pattern 76 may be formed to be in contact with the first electrode 71. In this case, the first bulk pattern 75A may be omitted.

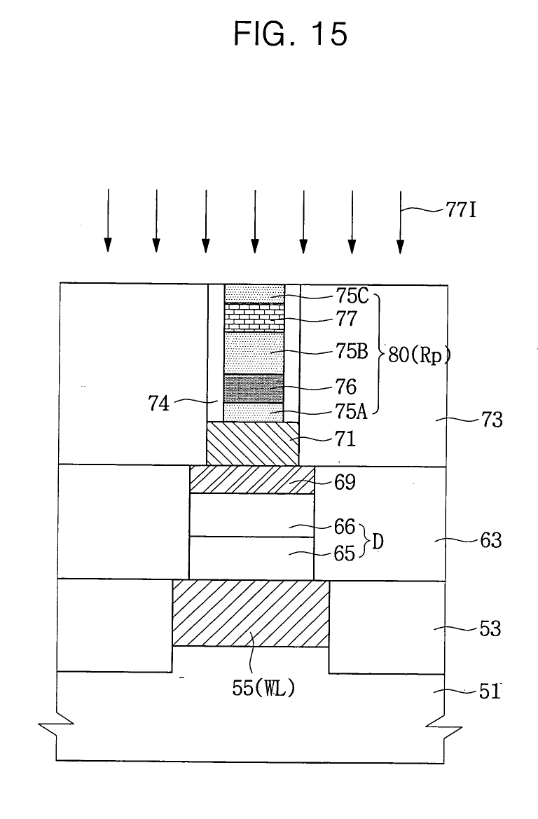

Referring to FIGS. 3 and 15, a second doping pattern 77 may be formed by performing a second ion implantation process 771 into the second bulk pattern 75B. The second doping pattern 77 may be formed by doping N, O, Bi, Sn, B, In, Ti, C and/or Si into the bulk pattern 75.

That is, the second doping pattern 77 may be formed by doping N, O, Bi, Sn, B, In, Ti, C and/or Si into a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

The second doping pattern 77 may be formed to have a higher doping concentration than the first doping pattern 76. The second doping pattern 77 may be formed by implanting the same doping material as the first doping pattern 76. Alternatively, the second doping pattern 77 may be formed by implanting different doping materials from the first doping pattern 76. The second doping pattern 77 may have a different electrical resistance from the first doping pattern 76. For example, the second doping pattern 77 may have a higher electrical resistance than the first doping pattern 76.

As a result, the bulk pattern 75 may be divided into the first bulk pattern 75A, the first doping pattern 76, the second bulk pattern 75B, the second doping pattern 77, and a third bulk pattern 75C. The first bulk pattern 75A, the first doping pattern 76, the second bulk pattern 75B, the second doping pattern 77, and the third bulk pattern 75C may be sequentially stacked on the first electrode 71. The first bulk pattern 75A, the first doping pattern 76, the second bulk pattern 75B, the second doping pattern 77, and the third bulk pattern 75C may form a phase change pattern (Rp) 80.

Alternatively, the first doping pattern 76 may be formed to be in contact with the second doping pattern 77. In this case, the phase change pattern 80 may include the first bulk pattern 75A, the first doping pattern 76, the second doping pattern 77, and the third bulk pattern 75C, which are sequentially stacked.

Also, the first doping pattern 76 may be formed to be in contact with the first electrode 71. Further, a top surface of the second doping pattern 77 may be exposed. In this case, the third bulk pattern 75C may be omitted.

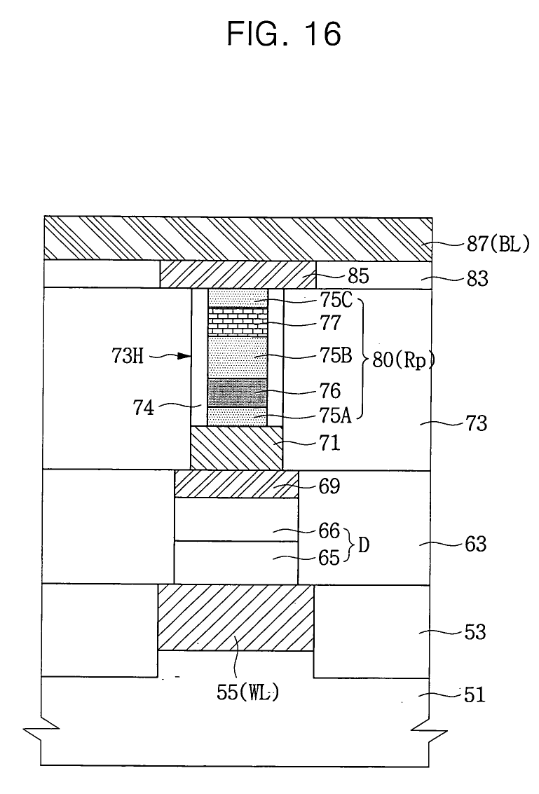

Referring to FIGS. 3 and 16, an upper insulating layer 83 may be formed on the interlayer insulating layer 73. The upper insulating layer 83 may include an insulating layer, such as a silicon oxide layer, a silicon nitride layer, a silicon oxynitride layer, and/or a combination thereof.

A second electrode 85 may be formed in the upper insulating layer 83 in contact with the phase change pattern 80. The second electrode 85 may be formed to cover the contact hole 73H. The width of the phase change pattern 80 adjacent to the second electrode 85 may be equal to or narrower than that of the second electrode 85. A bit line (BL) 87 crossing the second electrode 85 may be formed on the upper insulating layer 83.

The second electrode 85 may include a Ti layer, a TiN layer, a TiAlN layer, a W layer, a WN layer, a Si layer, a Ta layer, a TaN layer, a TaCN layer, and/or a WCN layer. The bit line 87 may include a conductive layer, such as a metal layer, a polysilicon layer, a metal silicide layer and/or a combination thereof.

The bit line 87 may be electrically connected to the word line 55 through the second electrode 85, the phase change pattern 80, the first electrode 71, the diode electrode 69, and the diode D. The first electrode 71, the first bulk pattern 75A, the first doping pattern 76, the second bulk pattern 75B, the second doping pattern 77, the third bulk pattern 75C, and the second electrode 85 may be connected in series.

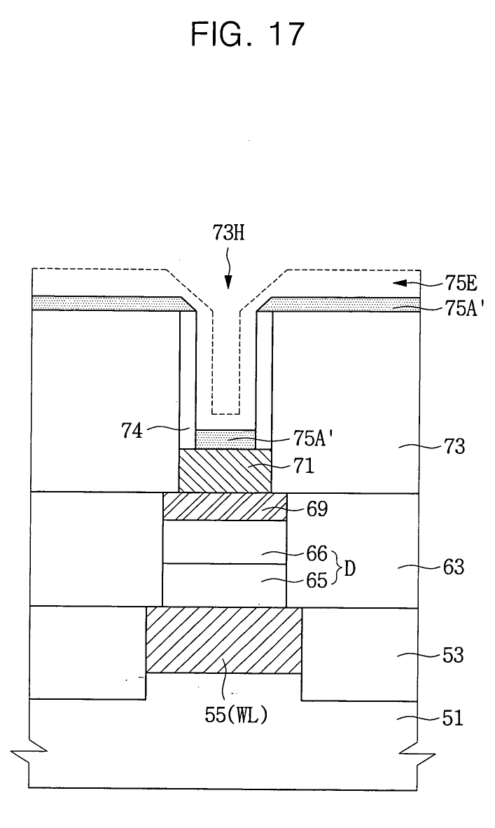

FIGS. 17 to 20 are cross-sectional views taken along line I-I′ of FIG. 3, illustrating further methods of fabricating a PRAM device according to embodiments of the present invention.

Referring to FIGS. 3 and 17, methods according to some embodiments may include forming a word line (WL) 55, an isolation layer 53, a lower insulating layer 63, a first semiconductor pattern 65, a second semiconductor pattern 66, a diode electrode 69, an interlayer insulating layer 73, a contact hole 73H, a first electrode 71, and a contact spacer 74 on a substrate 51 using methods similar to those described with reference to FIGS. 11 and 12. The first and second semiconductor patterns 65 and 66 may constitute a diode D.

A first bulk pattern 75A′ may be formed on the first electrode 71 and may at least partially fill the contact hole 73H. The first bulk pattern 75A′ may be formed by partially filling the contact hole 73H, depositing a first phase change material layer 75E on the interlayer insulating layer 73, and etching-back the first phase change material layer 75E.

For example, the formation of the first bulk pattern 75A′ may include alternately and repeatedly performing a deposition process and an etch-back process in the same chamber. In this case, portions of the first bulk pattern 75A′ may remain on the interlayer insulating layer 73.

The first bulk pattern 75A′ may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

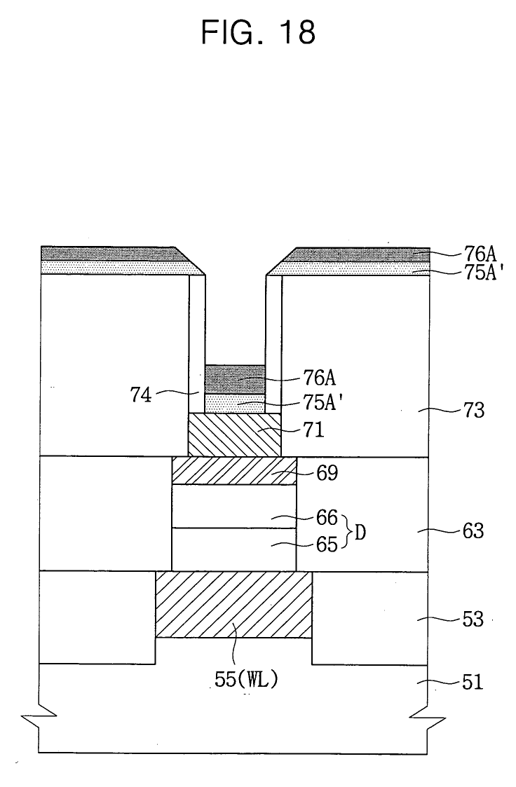

Referring to FIGS. 3 and 18, a first doping pattern 76A may be formed on the first bulk pattern 75A′. The first doping pattern 76A may be formed by doping N, O, Bi, Sn, B, In, Ti, C and/or Si into a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

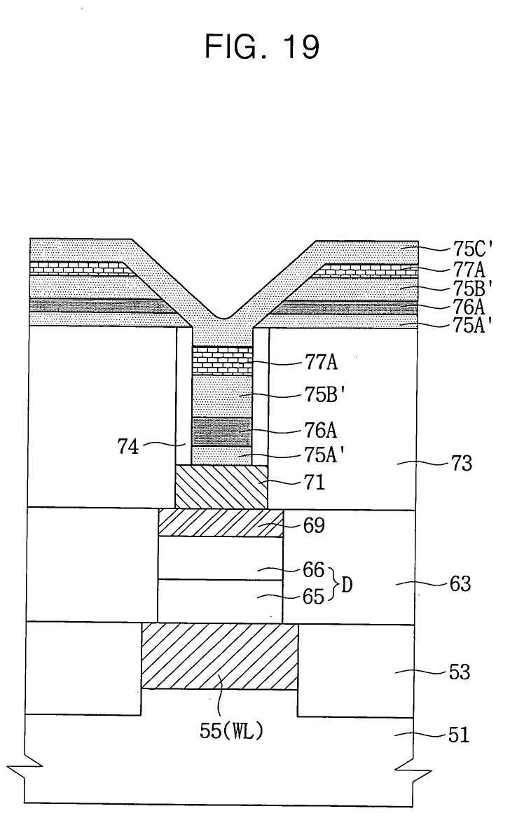

Referring to FIGS. 3 and 19, a second bulk pattern 75B′, a second doping pattern 77A, and a third bulk pattern 75C′ may be sequentially formed on the first doping pattern 76A. Each of the second bulk pattern 75B′ and the third bulk pattern 75C′ may include a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

The second doping pattern 77A may be formed by doping N, O, Bi, Sn, B, In, Ti, C and/or Si into a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

The second doping pattern 77A may have a higher doping concentration than the first doping pattern 76A. The second doping pattern 77A may be formed by implanting the same doping material as the first doping pattern 76A and/or a different doping material from the first doping pattern 76A. The second doping pattern 77A may have a different electrical resistance from the first doping pattern 76A. For example, the second doping pattern 77A may have a higher electrical resistance than the first doping pattern 76A.

The first bulk pattern 75A′ may be formed of the same material as the second bulk pattern 75B′ and the third bulk pattern 75C′. Further, the first bulk pattern 75A′, the first doping pattern 76A, the second bulk pattern 75B′, the second doping pattern 77A, and the third bulk pattern 75C′ may be formed by an in-situ process in the same chamber.

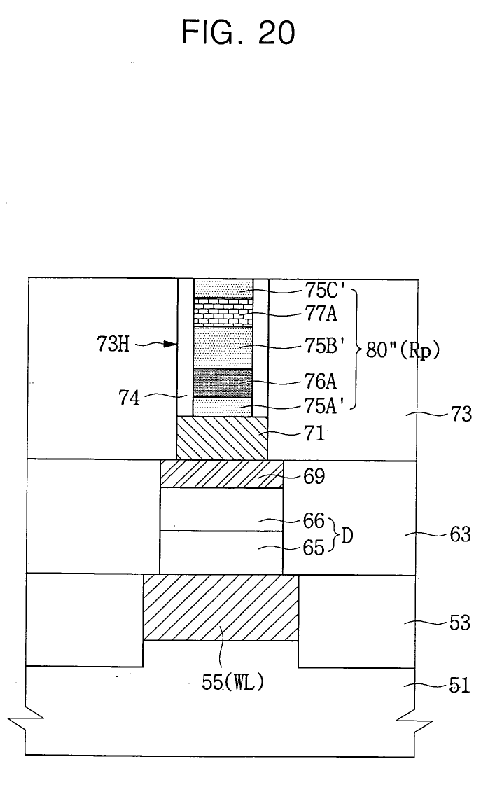

Referring to FIGS. 3 and 20, a phase change pattern (Rp) 80″ may be formed in the contact hole 73H by planarizing the third bulk pattern 75C′, the second doping pattern 77A, the second bulk pattern 75B′, the first doping pattern 76A, and the first bulk pattern 75A′.

The planarization may be performed by a CMP process adopting the interlayer insulating layer 73 as a stop layer. Alternatively, the planarization may be performed by an etch-back process.

As a result, the first bulk pattern 75A′, the first doping pattern 76A, the second bulk pattern 75B′, the second doping pattern 77A, and the third bulk pattern 75C′ may be sequentially stacked on the first electrode 71.

In some embodiments, the second bulk pattern 75B′ may be omitted, in which case the first doping pattern 76A may be formed to be in contact with the second doping pattern 77A. In other words, the first bulk pattern 75A′, the first doping pattern 76A, the second doping pattern 77A, and the third bulk pattern 75C′ may be sequentially stacked to thereby form the phase change pattern 80″.

Further, the first bulk pattern 75A′ may be omitted, in which case the first doping pattern 76A may be formed to be in contact with the first electrode 71.

Also, the third bulk pattern 75C′ may be omitted, in which case a top surface of the second doping pattern 77A may be exposed.

As described above, a structure may be formed including a first electrode on a substrate, a phase change pattern on the first electrode, and a second electrode on the phase change pattern. An interlayer insulating layer having a contact hole is provided on the substrate. The phase change pattern may be disposed in the contact hole. The phase change pattern includes a plurality of doping patterns. The doping patterns have different doping concentrations from each other. As a result, a multi-bit PRAM device having a relatively small transition volume may be implemented.

In the drawings and specification, there have been disclosed typical embodiments of the invention and, although specific terms are employed, they are used in a generic and descriptive sense only and not for purposes of limitation, the scope of the invention being set forth in the following claims.

What is claimed is:

1. A phase-change random access memory (PRAM) device, comprising:
a first electrode on a substrate;
a second electrode spaced apart from the first electrode; and
a phase change pattern including a plurality of doping patterns interposed between the first and second electrodes, wherein the doping patterns have different doping concentrations from each other.

2. The PRAM device of claim 1, further comprising an interlayer insulating layer on the substrate, wherein the phase change pattern is disposed in a contact hole passing through the interlayer insulating layer.

3. The PRAM device of claim 2, further comprising a contact spacer between the phase change pattern and the interlayer insulating layer.

4. The PRAM device of claim 1, wherein a portion of the phase change pattern adjacent to the first electrode has a width equal to or narrower than the first electrode, and a portion of the phase change pattern adjacent to the second electrode has a width equal to or narrower than the second electrode.

5. The PRAM device of claim 1, wherein the phase change pattern further comprises a bulk pattern, the bulk pattern comprising a Ge—Sb—Te layer, a Ge—Bi—Te layer, a Ge—Te—As layer, a Ge—Th—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer.

6. The PRAM device of claim 5, wherein the doping patterns are formed of a material in which N, O, Bi, Sn, B, In, Ti, C, and/or Si is added to the same material layer as the bulk pattern.

7. The PRAM device of claim 6, wherein the phase change pattern comprises:
a first doping pattern; and
a second doping pattern on the first doping pattern and having a higher doping concentration than the first doping pattern.

8. The PRAM device of claim 7, wherein the phase change pattern comprises:
a first bulk pattern interposed between the first electrode and the first doping pattern;
a second bulk pattern interposed between the first doping pattern and the second doping pattern; and
a third bulk pattern interposed between the second doping pattern and the second electrode.

9. A method of forming a PRAM device, comprising:
forming a first electrode on a substrate;
forming a phase change pattern having a plurality of doping patterns on the first electrode, wherein the doping patterns have different doping concentrations from each other; and
forming a second electrode on the phase change pattern.

10. The method of claim 9, further comprising:
forming an interlayer insulating layer on the substrate; and
forming a contact hole passing through the interlayer insulating layer,
wherein the phase change pattern is in the contact hole.

11. The method of claim 10, further comprising forming a contact spacer between the interlayer insulating layer and the phase change-pattern.

12. The method of claim 10, wherein the first electrode is formed in the contact hole.

13. The method of claim 10, wherein forming the phase change pattern comprises:
forming a bulk pattern in the contact hole, wherein the bulk pattern is connected to the first electrode;
forming a first doping pattern by performing a first ion implantation process into the bulk pattern; and
forming a second doping pattern by performing a second ion implantation process into the bulk pattern having the first doping pattern.

14. The method of claim 13, wherein the bulk pattern comprises a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer, and the doping patterns are formed of a material in which N, O, Bi, Sn, B, In, Ti, C, and/or Si is added to the same material layer as the bulk patterns.

15. The method of claim 13, wherein the first doping pattern and the first electrode are spaced apart from each other, and the first and second doping patterns are spaced apart from each other.

16. The method of claim 10, wherein forming the phase change pattern comprises:
depositing a first bulk pattern in contact with the first electrode in the contact hole;
depositing a first doping pattern on the first bulk pattern; and
depositing a second doping pattern on the first doping pattern.

17. The method of claim 16, further comprising depositing a second bulk pattern between the first and second doping patterns.

18. The method of claim 17, further comprising depositing a third bulk pattern on the second doping pattern.

19. The method of claim 18, wherein the bulk patterns comprise a Ge—Sb—Te layer, a Ge—Bi—Te layer, a Ge—Te—As layer, a Ge—Te—Sn layer, a Ge—Te layer, a Ge—Te—Sn—O layer, a Ge—Te—Sn—Au layer, a Ge—Te—Sn—Pd layer, a Ge—Te—Se layer, a Ge—Te—Ti layer, a Ge—Sb layer, a (Ge, Sn)—Sb—Te layer, a Ge—Sb—(SeTe) layer, a Ge—Sb—In layer, and/or a Ge—Sb—Te—S layer, and the doping patterns are formed of a material in which N, O, Bi, Sn, B, In, Ti, C, and/or Si is added to the same material layer as the doping patterns.

20. The method of claim 9, wherein a portion of the phase change pattern adjacent to the first electrode has a width equal to or narrower than the first electrode, and a portion of the phase change pattern adjacent to the second electrode has a width equal to or narrower than the second electrode.
